(19) United States
(12) Patent Application Publication
(10) Pub. No.: US 2004/0042178 A1
(43) Pub. Date: Mar. 4, 2004

(54) Heat spreader with surface cavity

(76) Inventors: Vadim Gektin, San Jose, CA (US); Deviprasad Malladi, Fremont, CA (US); Donald A. Kearns, Fremont, CA (US)

Correspondence Address: B. Noel Kivlin, Conley, Rose & Tayon, P.C., P.O. Box 398, Austin, TX, 78767, US

(21) Appl. No.: 10/233,858

(22) Filed: Sep. 3, 2002

(51) Int. Cl. H05K 7/20

(52) U.S. Cl. 361/705; 165/185; 174/16.3

(57) ABSTRACT

A heat spreader for cooling an electronic component. The heat spreader includes a thermal interface material disposed in a cavity in the body of the heat spreader. The thermal interface material is at least partially enclosed in the cavity by a surface of the electronic component or a heat sink.

### BACKGROUND OF THE INVENTION

1. Field of the Invention

The present invention relates generally to the field of electronic component heat dissipation. More particularly, this invention relates to an improved heat spreader for use with heat-producing electronic components.

2. Description of the Relevant Art

Thermal elements such as heat sinks are commonly attached to electronic components to facilitate heat dissipation from the components. A heat sink is typically composed of a thermally conductive material, such as aluminum, with a plurality of fins or pins on its exposed side. Heat is dissipated from the fins or pins to the surrounding air principally by thermal convection. Heat sinks may be coupled to a component by a variety of means known to those skilled in the art. For example, the heat sink may be coupled to the component by an adhesive or by various types of retainers such as clamps, brackets, or screws.

Some heat sinks are mounted to, consist of, or incorporate a thermally conductive element that facilitates distribution of heat from the surface of the component to the heat sink. The intermediary thermally conductive element may be referred to as a “heat spreader.” In some cases, the thermally conductive element may also function as a lid to physically protect the electronic component.

When a thermal element is mounted in direct contact with an electronic component, air gaps exist at the interface because of roughness and nonplanarity of the mating surfaces. These air gaps reduce the effectiveness of the thermal element because air has a relatively low thermal conductivity. For this reason, a thermal interface material, such as a thermal grease or paste, an elastomeric thermal pad, or a phase change material, is often placed between the thermal element and the electronic component to improve the performance of the thermal element.

A problem that arises from the use of thermal grease or similar materials is a phenomenon known as “pump-out.” “Pump-out” occurs when an electronic component is subjected to cyclic load conditions. Under cyclic loads, thermo-mechanical stresses between the electronic component and a heat sink or heat spreader may cause a loss of grease material from the interface. The loss of grease material may result in an increase in thermal resistance at the interface.

Elastomeric thermal pads may be used as an alternative to thermal grease. Elastomeric pads are not susceptible to pump-out. However, such pads may be difficult to position and maintain in place. Improper placement or slippage may result in increased thermal resistance at the interface. In some applications, special frames or similar components are used to facilitate placement and retention of the thermal interface material. However, such components add cost and complexity to the system in which they are used.

Regardless of the cause, increased thermal resistance at the interface between an electronic component and a thermal element results in higher operating temperatures of the component. Higher operating temperatures are associated with decreased reliability of electronic components. Accordingly, there is a need for an apparatus to improve thermal performance between an electronic component and a thermal element.

### SUMMARY OF THE INVENTION

In an embodiment, the body of a heat spreader includes a cavity that has an opening on the surface of the body. A thermal interface material, such as a resilient thermal pad, a thermal grease, or phase change material, may be disposed in the cavity to facilitate heat transfer from the component to the body of the heat spreader. The size and location of the opening of the cavity may be such that the cavity is at least partially enclosed by a surface of the component when the heat spreader is coupled to the component.

In an embodiment, the thermal interface material may be a resilient material, such as a thermally conductive elastomeric pad. The thickness of the thermal interface material may be chosen so that the thermal interface material is compressed between enclosing surface and the inner surfaces of the cavity when the heat spreader is coupled with the component.

In another embodiment, the thermal interface material may be a thermal grease. The thermal grease may substantially fill the cavity. The thermal grease may be at least partially contained by the inner surfaces of the cavity and the enclosing surface of the component during operation of the component. Containment of the thermal interface material within cavity may inhibit pump-out of the thermal interface material.

In another embodiment, the body of a heat spreader may include a cavity to accommodate thermal interface material between the heat spreader and a heat sink. In another embodiment, the thermal interface material can be disposed in a cavity formed in a heat sink instead of, or in addition to, a cavity in the body of the heat spreader. In another embodiment, a heat spreader may be incorporated into a computer system to facilitate heat transfer from one or more electronic components of the system.

### BRIEF DESCRIPTION OF THE DRAWINGS

Other objects and advantages of the invention will become apparent upon reading the following detailed description and upon reference to the accompanying drawings in which:

FIG. 1 shows an exploded perspective view of a heat sink, a heat spreader and an electronic component.

FIG. 2 shows a cross-sectional view of a heat spreader having two cavities positioned on a component.

FIG. 3 shows a cross-sectional view of a resilient thermal interface material disposed in a heat spreader body before it is coupled with a heat sink.

FIG. 4 shows a cross-sectional view of a heat transfer device, wherein the enclosing surfaces of a heat sink include side surfaces that face sidewalls of a heat spreader cavity.

FIG. 5 shows a cross-sectional view of a thermal interface material disposed in a cavity in a heat sink.

FIG. 6 shows a cross-sectional view of a thermal interface material disposed in matching cavities in a heat spreader and a heat sink.

FIG. 7 shows a block diagram of a computer system that incorporates one or more heat spreaders.

While the invention is susceptible to various modifications and alternative forms, specific embodiments thereof are shown by way of example in the drawing and will herein be described in detail. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims.

### DETAILED DESCRIPTION OF THE INVENTION

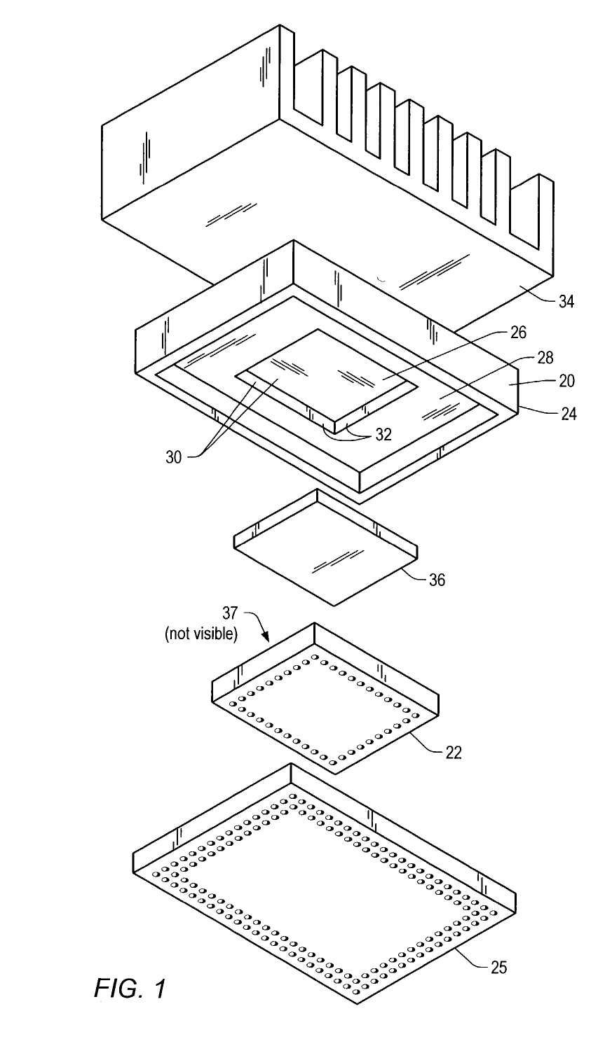

Referring now to FIG. 1, a heat spreader 20 may be mounted to a component 22 to facilitate cooling of the component. Component 22 may be any electronic component that produces heat during use, including, but not limited to, a surface-mounted integrated circuit, dual in-line memory module, or a single transistor housed in a can. Component 22 may be mounted to substrate 25, which may in turn be mounted to a printed circuit board (not shown). The package design of component 22 may be of a lidded or lidless type. Electrical connection of component 22 to substrate 25 may be by any means, including, but not limited to, ball grid array or pin grid array. Heat spreader 20 may be mounted either directly to component 22 or to another element, such as substrate 25 or a printed circuit board to which component 22 is also mounted.

Heat spreader 20 may include a body 24. Body 24 may be of a thermally conductive material. Examples of such materials include, but are not limited to, aluminum, copper, or brass. A cavity 26 may be disposed within body 24 having an opening on an outer surface 28 of body 24. Cavity 26 may have one or more inner surfaces 30, including sidewalls 32. Extended members such as fins or pins (not shown) for increasing the exposed surface area of the heat spreader 20 may be integral features of body 24. Alternatively, extended members may be part of a separate heat sink 34 that is coupled to a heat spreader 20 by screws, rivets, an adhesive, or other means known to those skilled in the art, to form a heat transfer device.

A thermal interface material 36 may be disposed in cavity 26 to facilitate heat transfer from component 22 to body 24 of heat spreader 20. Thermal interface material 36 may be any of a variety of thermal interface materials known to those skilled in the art, including, but not limited to, a resilient thermal pad, a thermal grease, a thermal paste, or a phase change film. Thermal interface material 36 may substantially fill cavity 26. Sidewalls 32 may inhibit movement of thermal interface material 36 during installation of heat spreader 20 or use of the electronic component, which may obviate the need for separate components to position and retain thermal interface material 36 in place on component 22.

The dimensions of the opening of cavity 26 may be smaller than dimensions of an enclosing surface 37 of component 22 (e.g., the upper surface of the component, not visible in FIG. 1) so that cavity 26 is at least partially enclosed by enclosing surface 37 when heat spreader 20 is coupled to the component. In some embodiments, thermal interface material 36 may be sealed in cavity 26 by installation of heat spreader 20 on component 22. In other embodiments, thermal interface material 36 may not be sealed in cavity 26, but merely inhibited from movement by inner surfaces 30 and enclosing surface 37.

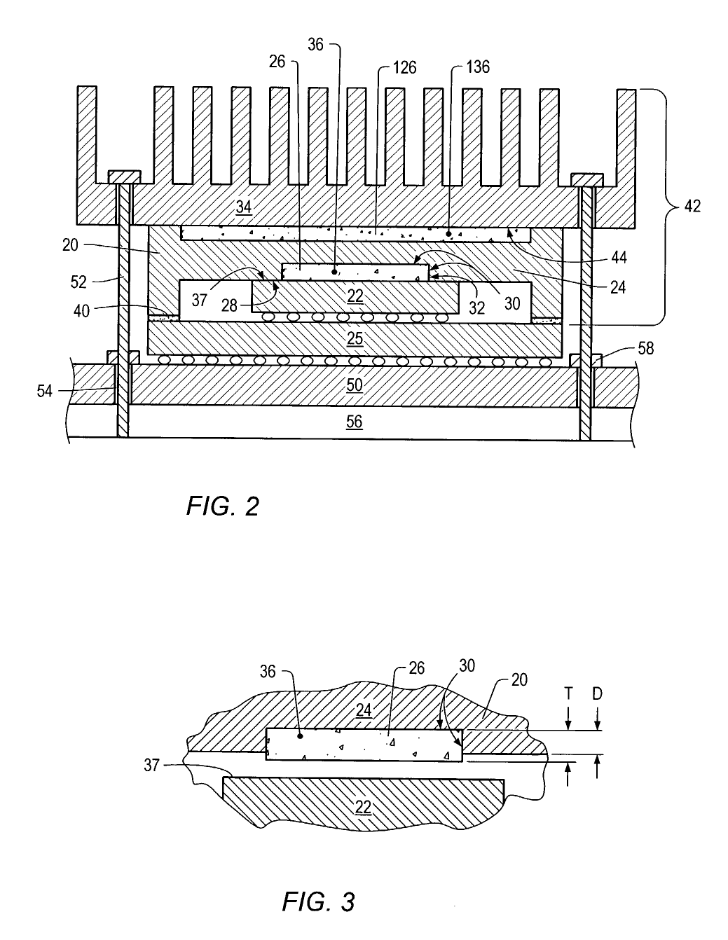

Heat spreader 20 may be coupled to component 22 by a variety of means. Such means include, but are not limited to, an adhesive, a retainer, or both. Adhesive 40 may be any of various thermally conductive epoxies or other bonding materials known to those skilled in the art. Referring to FIG. 2, adhesive 40 may be used to attach heat spreader 20 to substrate 25. A retainer may be any of various retaining elements known to those skilled in the art, including, but is not limited to, a clamp, a clip, a bracket, or one or more screws. FIG. 2 shows a heat transfer device 42 mounted to a printed circuit board 50 by a plurality of screws 52. Heat transfer device 42 includes heat spreader 20 and a heat sink 34. Screws 52 may extend through a matching pattern of holes 54 in printed circuit board 50. Screws 52 may be affixed to a bolster plate 56, and the parts maintained in relative position to each other by nuts 58.

In an embodiment, thermal interface material 36 may be a resilient material. For example, thermal interface material 36 may be a thermally conductive elastomeric pad. As shown in FIG. 3, the free thickness T of thermal interface material 36 may be chosen so that thermal interface material 36 is compressed between enclosing surface 37 and inner surfaces 30 when heat spreader 20 is coupled with component 22. For example, the depth D of cavity 26 may be 25% less than free thickness T of thermal interface material 36. Compression of the resilient material in cavity 26 may reduce thermal contact resistance between thermal interface material 36 and enclosing surface 37 and between thermal interface material 36 and inner surfaces 30, which may improve the thermal performance of heat spreader 20.

In another embodiment, thermal interface material may be a thermal grease. As shown in FIG. 2, the thermal grease may substantially fill cavity 26. The thermal grease may be at least partially contained by inner surfaces 30 and enclosing surface 37 during operation of component 22. Containment of the thermal grease within cavity 26 may inhibit pump-out of the thermal grease.

In an embodiment, a heat spreader may have a cavity for accommodating thermal interface material on a surface that faces a heat sink. FIG. 2 shows a heat spreader 20 having a cavity 126 in which thermal interface material 136 is disposed. When heat sink 34 is coupled to heat spreader 20, thermal interface material 136 may be partially enclosed by enclosing surface 44 of heat sink 34.

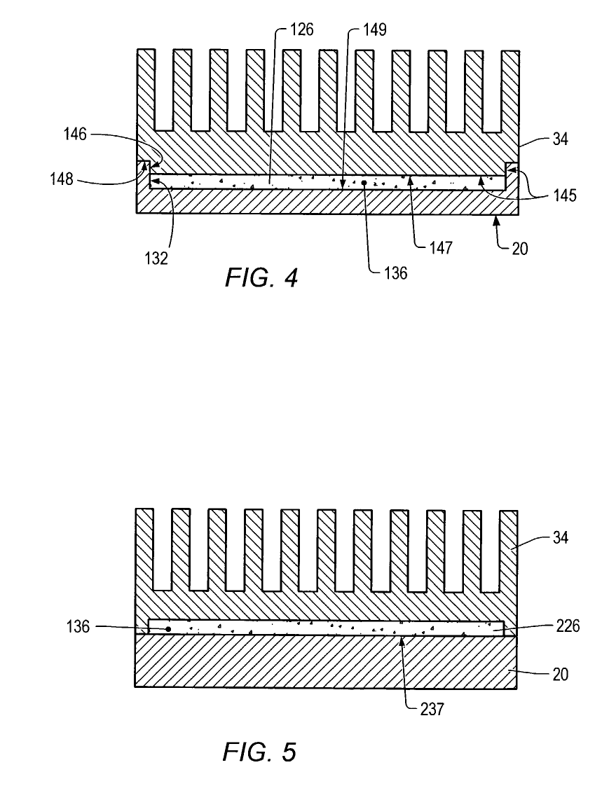

In an embodiment, a cavity may be at least partially enclosed by a plurality of surfaces that face the sidewalls of the cavity. FIG. 4 shows a heat sink 34 having enclosing surfaces 145 that include side surfaces 146 and front surface 147. Side surfaces 146 face a portion of sidewalls 132. Stop 148 of heat sink 34 may control spacing between front surface 147 and bottom surface 149 of cavity 126 so that the desired level of compression of thermal interface material 136 may be achieved.

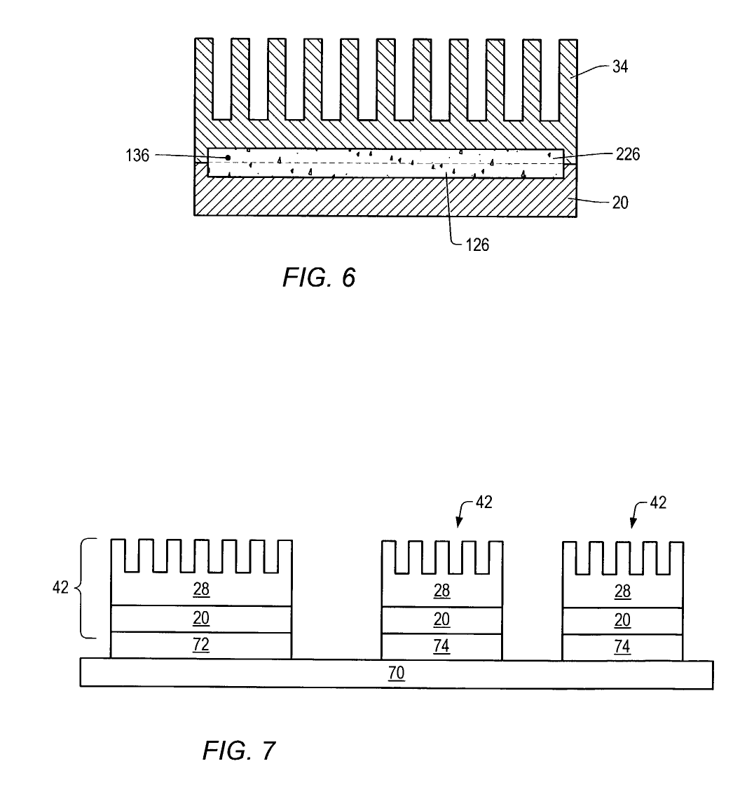

In some embodiments, the thermal interface material can be disposed in a cavity formed in a heat sink instead of, or in addition to, a cavity in the body of a heat spreader. FIG. 5 shows thermal interface material 136 enclosed in a cavity 226 of a heat sink 34 by enclosing surface 237 of heat spreader 20. FIG. 6 shows thermal interface material 136 enclosed in a cavity 126 of heat spreader 20 and a cavity 226 of heat sink 34.

In an embodiment, heat spreader 20 may be incorporated into a computer system to facilitate heat transfer from one or more electronic components of the system. FIG. 7 is a high-level component diagram of such a computer system. Computer system 70 may include a central processing unit 72 and other electronic components 74. Heat transfer devices 42 may be coupled to central processing unit 72 and to electronic components 74. Heat transfer devices 42 include a heat spreader 20, as described herein, and a heat sink 34.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A heat spreader for cooling an electronic component, comprising:
a body, the body comprising a cavity having an opening on a surface of the body; and
a thermal interface material disposed in the cavity;
wherein the cavity is adapted to be at least partially enclosed by a surface of the electronic component during use.

2. The heat spreader of claim 1, wherein the cavity is sealed when the heat spreader is coupled to the electronic component.

3. The heat spreader of claim 1, wherein the thermal interface material substantially fills the cavity.

4. The heat spreader of claim 1, wherein thermal interface material comprises a thermal grease.

5. The heat spreader of claim 1, wherein thermal interface material comprises a resilient material adapted to be compressible within the cavity when the heat spreader is coupled to the electronic component.

6. The heat spreader of claim 1, wherein the thermal interface material comprises a resilient material adapted to be compressible within the cavity by at least about 25% when the heat spreader is coupled to the electronic component.

7. A heat transfer device for cooling an electronic component comprising:
a heat spreader comprising:
a body, the body comprising a cavity having an opening on a surface of the body; and
a thermal interface material disposed in the cavity; and
a heat sink coupled to the heat spreader;
wherein the cavity is adapted to be at least partially enclosed when the heat transfer device is assembled and installed on the electronic component.

8. The heat transfer device of claim 7, wherein the cavity is at least partially enclosed by a surface of the electronic component.

9. The heat transfer device of claim 7, wherein the cavity is at least partially enclosed by a surface of the heat sink.

10. The heat transfer device of claim 7, wherein the cavity is sealed when the heat transfer device is assembled and installed on the electronic component.

11. The heat transfer device of claim 7, wherein the thermal interface material substantially fills the cavity.

12. The heat transfer device of claim 7, wherein thermal interface material comprises a thermal grease.

13. The heat transfer device of claim 7, wherein thermal interface material comprises a resilient material adapted to be compressible within the cavity when the heat transfer device is assembled and installed on the electronic component.

14. The heat transfer device of claim 7, wherein the thermal interface material comprises a resilient material adapted to be compressible within the cavity by at least about 25% when the heat spreader when the heat transfer device is assembled and installed on the electronic component.

15. The heat transfer device of claim 7, wherein the heat sink is removably attachable to the heat spreader.

16. A computer system comprising:
at least one heat producing electronic component; and
a heat spreader coupled to at least one of the heat producing electronic components, the heat spreader comprising:
a body, the body comprising a cavity having an opening on a surface of the body; and
a thermal interface material disposed in the cavity;
wherein the cavity is adapted to be at least partially enclosed by a surface of the electronic component.

17. The computer system of claim 16, wherein the cavity is sealed when the heat spreader is coupled to the electronic component.

18. The computer system of claim 16, wherein the thermal interface material substantially fills the cavity.

19. The computer system of claim 16, wherein thermal interface material comprises a thermal grease.

20. The computer system of claim 16, wherein thermal interface material comprises a resilient material adapted to be compressible within the cavity when the heat spreader is coupled to the electronic component.

21. The computer system of claim 16, wherein the thermal interface material comprises a resilient material adapted to be compressible within the cavity by at least about 25% when the heat spreader is coupled to the electronic component.
